(19) United States
(12) Patent Application Publication
(10) Pub. No.: US 2026/0088793 A1
(43) Pub. Date: Mar. 26, 2026

(54) ELECTRONIC COMPONENT

(71) Applicant: Murata Manufacturing Co., Ltd., Kyoto-fu (JP)

(72) Inventors: Tomoyoshi HIEI, Nagaokakyo-shi (JP); Satoshi SHIGEMATSU, Nagaokakyo-shi (JP)

(73) Assignee: Murata Manufacturing Co., Ltd., Kyoto-fu (JP)

(21) Appl. No.: 19/404,944

(22) Filed: Dec. 1, 2025

Related U.S. Application Data
(63) Continuation of application No. PCT/JP2024/005976, filed on Feb. 20, 2024.

(30) Foreign Application Priority Data
Jun. 6, 2023 (JP) 2023-093242

(51) Int. Cl. H03H 7/01; H01F 27/28; H01F 27/32; H01F 27/40; H01G 4/008; H01G 4/30; H01G 4/38; H01G 4/40; H03H 1/00

(52) U.S. Cl. CPC H03H 7/0115; H01F 27/2804; H01F 27/323; H01F 27/40; H01G 4/008; H01G 4/30; H01G 4/38; H01G 4/40; H03H 1/00; H03H 7/1708; H01F 2027/2809; H03H 2001/0085

(57) ABSTRACT

An electronic component that can suppress occurrence of problems such as electrochemical migration. An electronic component includes an insulator where a plurality of insulating substrates, each being provided with a side electrode and an inner electrode, are placed upon each other; and outer electrodes that are electrically connected to the side electrodes and that are provided at side surfaces of the insulator. The plurality of insulating substrates are each further provided with dummy electrodes that are disposed on a corresponding one of two sides of the side electrode with an insulating portion being interposed therebetween when viewed from a placement direction. The outer electrodes are electrically connected to the dummy electrodes at the side surfaces of the insulator.

### CROSS-REFERENCE TO RELATED APPLICATIONS

This application claims benefit of priority to International Patent Application No. PCT/JP2024/005976, filed Feb. 20, 2024, and to Japanese Patent Application No. 2023-093242, filed Jun. 6, 2023, the entire contents of each are incorporated herein by reference.

### BACKGROUND

### Technical Field

The present disclosure relates to an electronic component where an outer electrode is provided at a side surface of an insulator.

### Background Art

In an electronic component where an outer electrode is provided at a side surface of an insulator, when a gap is formed between the insulator and the outer electrode, there may occur problems such as electrochemical migration caused by entry of moisture into the insulator through the gap. Japanese Unexamined Patent Application Publication No. 2004-273917 discloses a structure of an electronic component that prevents entry of moisture.

### SUMMARY

In Japanese Unexamined Patent Application Publication No. 2004-273917, by forming a protruding convex-shaped portion at a side of an extended portion of an inner electrode, entry of moisture along the vicinity of a side edge of the extended portion from an end surface of the electronic component is prevented from occurring. However, merely providing the convex-shaped portion at the inner electrode cannot suppress occurrence of problems such as electrochemical migration occurring between the inner electrode and a side electrode electrically connected to an outer electrode.

Accordingly, the present disclosure provides an electronic component that can suppress occurrence of problems such as electrochemical migration.

An electronic component according to an aspect of the present disclosure includes an insulator where a plurality of insulating substrates, each being provided with a side electrode and an inner electrode, are placed upon each other; and outer electrodes that are electrically connected to the side electrodes and that are provided at side surfaces of the insulator. The plurality of insulating substrates are each further provided with dummy electrodes that are disposed on a corresponding one of two sides of the side electrode with an insulating portion being interposed therebetween when viewed from a placement direction. The outer electrodes are electrically connected to the dummy electrodes at the side surfaces of the insulator.

According to the aspect of the present disclosure, since the plurality of insulating substrates are each further provided with the dummy electrodes that are disposed on the corresponding one of the two sides of the side electrode with the insulating portion being interposed therebetween when viewed from the placement direction, it is possible to suppress occurrence of problems such as electrochemical migration.

### BRIEF DESCRIPTION OF THE DRAWINGS

FIG. 1 is a perspective view of an electronic component according to an embodiment;

FIG. 2 is a circuit diagram of the electronic component according to the embodiment;

FIG. 3 is a plan view of the vicinity of one outer electrode of the electronic component according to the embodiment;

FIG. 4 is a sectional view of the vicinity of one outer electrode of the electronic component according to the embodiment;

FIG. 5 is an exploded plan view showing a structure of the electronic component according to the embodiment;

FIG. 6 is an exploded plan view showing a structure of an electronic component according to Modification 1;

FIG. 7 is an exploded plan view showing a structure of an electronic component according to Modification 2; and

FIG. 8 is a plan view of the vicinity of one outer electrode of an electronic component according to Modification 3.

### DETAILED DESCRIPTION

An electronic component according to an embodiment is described below. In the electronic component that is described below, in a rectangular parallelepiped insulator, a filter circuit including a coil and a capacitor is constituted by inner electrodes. However, in the electronic component according to the present disclosure, as long as a structure in which outer electrodes are provided at side surfaces of the insulator is used, the filter circuit need not be constituted by the inner electrodes and another circuit may be constituted by the inner electrodes.

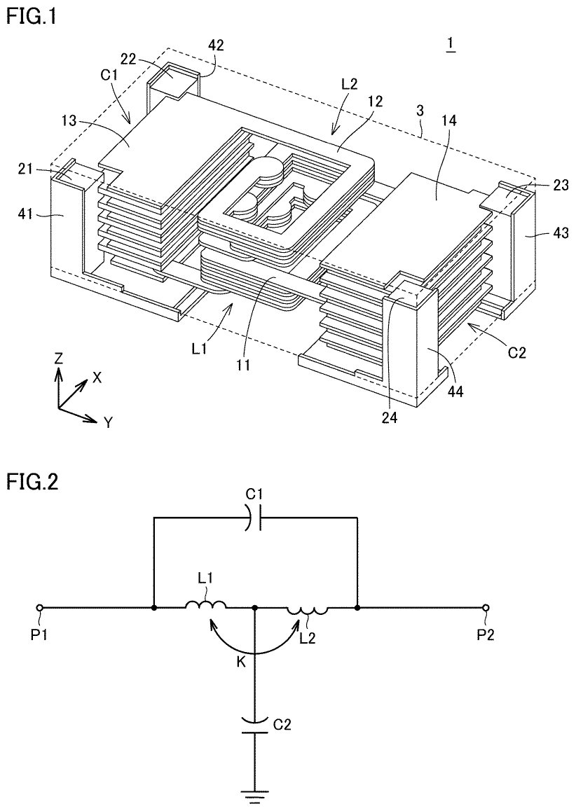

First, the electronic component according to the embodiment is described with reference to the drawings. FIG. 1 is a perspective view of an electronic component 1 according to the embodiment. FIG. 2 is a circuit diagram of the electronic component 1 according to the embodiment. Here, in FIG. 1, a short side direction of the electronic component 1 is an X direction, a long side direction thereof is a Y direction, and a height direction thereof is a Z direction. A placement direction of insulating substrates (hereunder may also be simply referred to as “substrates”) is the Z direction, and the direction of an arrow is an upper layer direction.

The electronic component 1 is a filter circuit where a first coil L1 and a second coil L2, which constitute a transformer, are disposed in the placement direction and where a first capacitor C1 and a second capacitor C2 are disposed in the Y direction.

In the electronic component 1, as shown in FIG. 2, the first coil L1 and the second coil L2, which are magnetically coupled to each other, are connected in series between a first terminal P1 and a second terminal P2. Further, in the electronic component 1, the first capacitor C1 is connected in parallel to the first coil L1 and the second coil L2, and an intermediate terminal that is provided between the first coil L1 and the second coil L2 is connected to ground (GND) through the second capacitor C2.

As shown in FIGS. 1 and 2, the electronic component 1 includes an insulator 3 where a plurality of substrates, at each of which inner electrodes constitute parts of the coils corresponding thereto and inner electrodes constitute parts of the capacitors corresponding thereto, are placed upon each other. It should be noted that four side electrodes, each constituting a corresponding one of the first terminal P1, the second terminal P2, the GND terminal, and an unused terminal (NC terminal), are formed at four corners of each substrate. For example, the insulator 3 may be produced by using a technique of forming electrode patterns of the side electrodes and the inner electrodes with a photomask by using a photosensitive conductive paste and a photosensitive insulating paste. Alternatively, for example, the insulator 3 may be produced by using a step of forming electrode patterns by screen printing or a step of forming a hole in an insulating layer with laser and filling the hole with a via electrode, to use a technique of placing ceramic green sheets, which are insulating substrates, upon each other.

The insulator 3 has a first main surface and a second main surface that form a pair and that face each other, and side surfaces that connect the first main surface and the second main surface. As shown in FIG. 1, in the insulator 3, the substrates, at each of which an inner electrode 11 of the first coil L1, an inner electrode 12 of the second coil L2, an inner electrode 13 of the first capacitor C1, and an inner electrode 14 of the second capacitor C2 are formed, are placed upon each other in the Z direction, the inner electrodes 11 to 14 constituting the filter circuit.

When viewed from the placement direction, a side electrode 21 that constitutes the first terminal P1, a side electrode 22 that constitutes the second terminal P2, a side electrode 23 that constitutes the GND terminal, and a side electrode 24 that constitutes the unused terminal (NC terminal) are each formed at a corresponding one of the four corners of the insulator 3. The shapes of outer electrodes 41 to 44 when viewed from the placement direction are square shapes. It should be noted that the side electrodes 21 to 24 need not be formed at the four corners of the insulator 3 and are to be formed at outer peripheral sides of the insulator 3. The side electrodes 21 to 24 that are formed at the outer peripheral sides of the insulator 3 are each electrically connected to a corresponding one of the outer electrodes 41 to 44 that are formed at the side surfaces of the insulator 3.

The outer electrodes 41 to 44 may be formed not only at the side surfaces of the insulator 3, but also at a bottom surface (the second main surface) of the insulator 3 as shown in FIG. 1. Obviously, the outer electrodes 41 to 44 may be formed not only at the bottom surface (the second main surface) of the insulator 3, but also at a top surface (the first main surface) of the insulator 3. It should be noted that the outer electrodes 41 to 44 are thin-film layers that are formed at the side surfaces and the bottom surface of the insulator 3, and are plating layers. For example, when the side electrodes 21 to 24 are formed from silver (Ag) paste, in order to facilitate soldering of the electronic component 1 to a mounting board, the outer electrodes 41 to 44 are formed from gold (Au) plating layers.

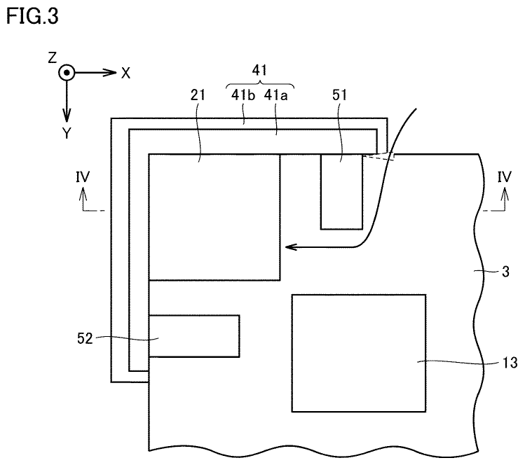

However, since, when the gold (Au) plating layers are directly formed at the side electrodes 21 to 24 formed from silver (Ag) paste, close contact ability is poor, the outer electrodes 41 to 44 each include two layers in which, after a nickel (Ni) plating layer is formed, the gold (Au) plating layer is formed. FIG. 3 is a plan view of the vicinity of one outer electrode 41 of the electronic component 1 according to the embodiment. In FIG. 3, the outer electrode 41 including a nickel (Ni) plating layer 41a (a first outer electrode layer) and a gold (Au) plating layer 41b (a second outer electrode layer) is provided at side surfaces of the insulator 3 where the side electrode 21 is formed.

When the outer electrode 41 is provided at the side surfaces of the insulator 3 where the side electrode 21 is formed in this way, a gap may be formed at an interface between a side surface of the side surfaces of the insulator 3 and the outer electrode 41. In particular, when the gold (Au) plating layer 41b is formed after forming the nickel (Ni) plating layer 41a, the nickel (Ni) plating layer 41a may be eluted (undergo Ni corrosion) when forming the gold (Au) plating layer 41b, and thus a gap is formed at the interface between the side surface of the insulator 3 and the outer electrode 41. When the gap is formed at the interface between the side surface of the insulator 3 and the outer electrode 41, problems such as electrochemical migration caused by entry of moisture into the insulator 3 through the gap may occur.

Therefore, in the electronic component 1 of the present embodiment, dummy electrodes 51 and 52 are provided so as to be disposed on a corresponding one of two sides of the side electrode 21 with an insulating portion being interposed therebetween when viewed from the placement direction (the Z direction). It should be noted that, in the electronic component 1 shown in FIG. 1, the dummy electrodes are not shown. In FIG. 3, a gap that is formed at the interface between a side surface of the side surfaces of the insulator 3 and the outer electrode 41 is indicated by a broken-line triangular shape, and moisture that enters through the gap is indicated by an arrow. By providing the dummy electrode 51, the moisture that has entered through the gap cannot reach the side electrode 21 unless that moisture bypasses the dummy electrode 51, and thus it is possible to suppress occurrence of problems such as electrochemical migration occurring between the side electrode 21 and the inner electrode 13. That is, by providing the dummy electrodes 51 and 52, it is possible to extend a path extending from an edge of the outer electrode 41 to the side electrode 21 and to make longer an entry path of the moisture that enters the insulator 3.

The outer electrode 41 is provided from where the side electrode 21 is disposed to where the dummy electrodes 51 and 52 are disposed, and is connected to the dummy electrodes 51 and 52 at the side surfaces of the insulator 3. That is, the outer electrode 41 is connected to not only the side electrode 21 but also the dummy electrodes 51 and 52. When the insulator 3 is formed from, for example, a glass body, the side electrode 21 and the dummy electrodes 51 and 52 have a higher degree of contact than the glass body with respect to the outer electrode 41 that is a plating layer. It should be noted that, although the dummy electrodes 51 and 52 are formed from a material, such as a silver (Ag) paste, that is the same as that of the side electrode 21, the dummy electrodes 51 and 52 may be formed from a material differing from that of the side electrode 21 as along as the material of the dummy electrodes 51 and 52 has a higher degree of contact than the glass body with respect to the outer electrode 41.

It should be noted that, when the dummy electrodes 51 and 52 are made of a material that is the same as the material of the side electrode 21, even if, by providing the dummy electrodes 51 and 52, the area of the side electrode 21 is decreased, it is possible to suppress a decrease in the degree of contact between the outer electrode 41 and the insulator 3. When the insulator 3 is to be fired, a stress that peels the side electrode 21 from the insulator 3 is produced due to a difference between the thermal shrinkage rate of the insulator 3, which is formed from a glass body, and the thermal shrinkage rate of the side electrode 21, which is made of a metal; however, when the dummy electrodes 51 and 52 are provided, the area of the side electrode 21 is decreased, and thus the stress that causes the peeling is decreased, thereby making it possible to suppress occurrence of delamination.

A gap is formed between the insulator 3, which is formed from a glass body, and the side electrode 21, which is made of a metal, and between the insulator 3 and the dummy electrodes 51 and 52 due to a difference between the thermal shrinkage rate of the insulator 3 and the thermal shrinkage rate of the side electrode 21, and a difference between the thermal shrinkage rate of the insulator 3 and the thermal shrinkage rates of the dummy electrodes 51 and 52; however, the outer electrode 41 that is formed after the firing of the insulator 3 is such that a gap is unlikely to be formed between the outer electrode 41 and the side electrode 21 and between the outer electrode 41 and the dummy electrodes 51 and 52. Therefore, since the moisture enters along outer peripheral surfaces of the dummy electrodes 51 and 52 without entering locations between the outer electrode 41 and the dummy electrodes 51 and 52, it is possible to extend an entry path.

Further, as shown in FIG. 3, it is preferable that the shapes of the dummy electrodes 51 and 52 when viewed from the placement direction (the Z direction) each be a rectangular shape whose side that does not contact the outer electrode 41 is longer than a side thereof that contacts the outer electrode 41. This makes it possible to ensure the lengths of the outer peripheries of the dummy electrodes 51 and 52. It should be noted that the shapes of the dummy electrodes 51 and 52 are each not limited to a rectangular shape, and thus may be, for example, a triangular shape, a circular shape, or a polygonal shape.

As shown in FIG. 3, it is preferable that the distance between the dummy electrode 51 and the inner electrode 13 and the distance between the dummy electrode 52 and the inner electrode 13 be larger than the distance between the side electrode 21 and the inner electrode 13. This makes it possible to prevent formation of an entry path where moisture enters from the dummy electrode 51 to the inner electrode 13 and formation of an entry path where moisture enters from the dummy electrode 52 to the inner electrode 13. Here, the distance refers to a shortest distance connecting the side electrode 21 and the inner electrode 13.

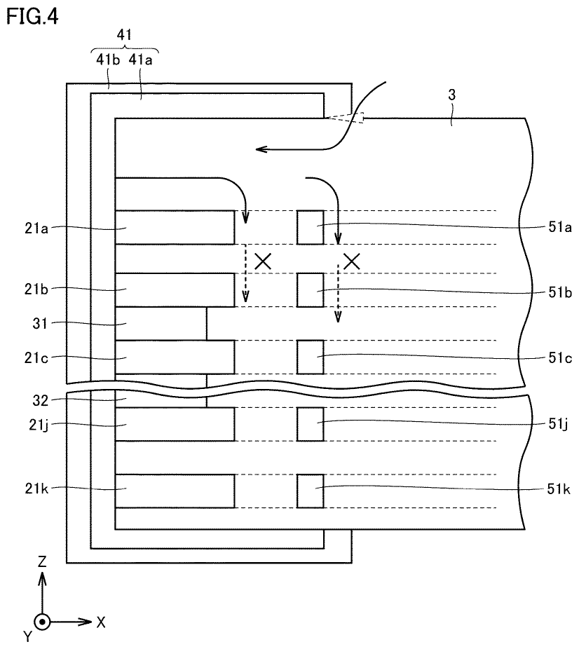

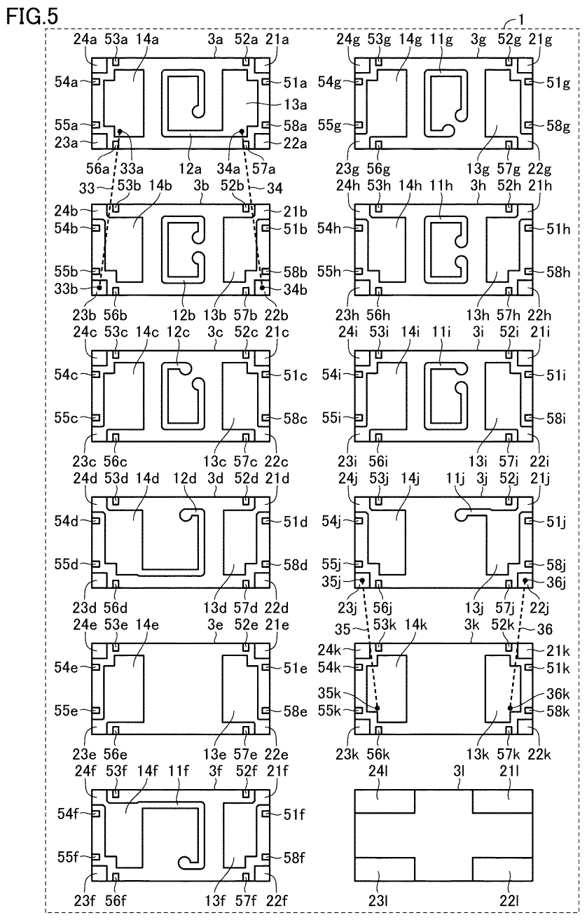

Although in FIG. 3, the entry of moisture in a planar direction (XY direction) of the insulator 3 is described, moisture may also enter in the placement direction (the Z direction) of the insulator 3. FIG. 4 is a sectional view of the vicinity of one outer electrode 41 of the electronic component 1 according to the embodiment. The sectional view of FIG. 4 is a sectional view of an IV-IV plane in FIG. 3. It should be noted that the electronic component 1 shown in FIG. 4 differs from the electronic component 1 shown in FIG. 1 in that the outer electrode 41 is also provided at the top surface of the insulator 3.

In FIG. 4, when a gap is formed at an interface between the top surface of the insulator 3 and the outer electrode 41, problems such as electrochemical migration caused by entry of moisture into the insulator 3 through the gap may occur. Therefore, in the electronic component 1 according to the present embodiment, a side electrode 21a (a first side electrode) that is closest to the top surface of the insulator 3 and a side electrode 21b (a second side electrode) that is closer by a distance corresponding to one layer to the bottom surface of the insulator 3 than the side electrode 21a are not electrically connected to each other by a via conductor. It should be noted that the disclosure is not limited to the case in which the side electrode 21b is provided lower than the side electrode 21a by the distance corresponding to one layer, and that at least one layer of an insulating substrate where a side electrode and an inner electrode are not formed may be interposed between the side electrode 21a and the side electrode 21b. That is, the side electrode 21b is to be adjacent to the side electrode 21a at a position closer to the bottom surface of the insulator 3 than the side electrode 21a.

Therefore, even if moisture enters as indicated by an arrow through the gap (broken-line triangular shape) that is formed at the interface between the top surface of the insulator 3 and the outer electrode 41, since the side electrode 21a is not connected to the side electrode 21b by a via conductor, the entered moisture cannot reach the side electrode 21b unless the moisture bypasses the side electrode 21a, and thus it is possible to suppress occurrence of problems such as electrochemical migration occurring between the side electrode 21b and the inner electrode. That is, when the side electrode 21a and the side electrode 21b are not connected to each other by a via conductor, it is possible to extend a path extending from an edge of the outer electrode 41 to the side electrode 21b and to make longer an entry path of the moisture that enters the insulator 3. It should be noted that a dummy electrode 51a provided in a layer that is the same as that of the side electrode 21a also contributes to making longer the entry path of the moisture that enters the insulator 3.

Since a gap may be formed at the interface between the bottom surface of the insulator 3 and the outer electrode 41, similarly, in the electronic component 1 of the present embodiment, a side electrode 21k (a third side electrode) that is closest to the bottom surface of the insulator 3 and a side electrode 21j (a fourth side electrode) that is closer by a distance corresponding to one layer to the top surface of the insulator 3 than the side electrode 21k are not electrically connected to each other by a via conductor. It should be noted that the disclosure is not limited to the case in which the side electrode 21j is provided higher than the side electrode 21k by the distance corresponding to one layer, and that at least one layer of an insulating substrate where a side electrode and an inner electrode are not formed may be interposed between the side electrode 21k and the side electrode 21j. That is, the side electrode 21j is to be adjacent to the side electrode 21k at a position closer to the top surface of the insulator 3 than the side electrode 21k. Therefore, it is possible to extend a path extending from an edge of the outer electrode 41 to the side electrode 21j and to make longer an entry path of the moisture that enters the insulator 3. It should be noted that a dummy electrode 51k provided in a layer that is the same as that of the side electrode 21k also contributes to making longer the entry path of the moisture that enters the insulator 3.

In the electronic component 1, except for the side electrode 21a and the side electrode 21b and for the side electrode 21k and the side electrode 21j, the side electrodes of the respective layers are electrically connected to each other by respective via conductors. Specifically, the side electrode 21b and a side electrode 21c are electrically connected to each other by a via conductor 31, and further the side electrode 21c and a side electrode 21d (not shown) are electrically connected to each other by a via conductor 32. It should be noted that the disclosure is not limited to the case in which, except for the side electrode 21a and the side electrode 21b and for the side electrode 21k and the side electrode 21j, all of the side electrodes of the respective layers are electrically connected to each other by the respective via conductors, and thus the side electrodes of some of the layers are to be electrically connected to each other by the respective via conductors. Obviously, there may be a case in which none of the side electrodes of the respective layers are electrically connected to each other by respective via conductors.

It is preferable that the via conductors (such as the via conductors 31 and 32) that electrically connect the side electrodes of the respective layers to each other be directly electrically connected to the outer electrode 41. By directly electrically connecting the via conductors and the outer electrode 41, it is possible to keep low the electrical resistance between the outer electrode 41 and the side electrodes. Obviously, if the electrical resistance is low, the outer electrode 41 and the via conductors (such as the via conductors 31 and 32) that connect the side electrodes of the respective layers to each other need not be directly electrically connected to each other.

Although, in each of FIGS. 3 and 4, the structure of the vicinity of the outer electrode 41 has been described, in the electronic component 1, the vicinities of the other outer electrodes 42 to 44 have structures that are the same as the structure of the vicinity of the outer electrode 41, and thus it is possible to suppress occurrence of problems such as electrochemical migration occurring between the side electrodes and the inner electrodes corresponding thereto. Although, in the electronic component 1, the dummy electrodes 51 and 52 shown in FIG. 3 are used, the structure shown in FIG. 4 need not be used.

Next, a structure of each layer is described by using an exploded plan view. FIG. 5 is an exploded plan view showing a structure of the electronic component 1 according to the embodiment. First, for example, as shown in FIG. 5, by using a screen printing method, electrode patterns of side electrodes and inner electrodes of coils and capacitors are each formed from a conductive paste (Ag paste) at a corresponding one of insulating substrates 3a 3l, which are substrates.

As shown in FIG. 5, side electrodes 21a to 24a and dummy electrodes 51a to 58a are formed at the insulating substrate 3a. Further, an inner electrode 12a that constitutes a part of a second coil L2, an inner electrode 13a that constitutes a part of a first capacitor C1, and an inner electrode 14a that constitutes a part of a second capacitor C2 are formed at the insulating substrate 3a. The inner electrode 12a is electrically connected to the inner electrode 13a.

Side electrodes 21b to 24b and dummy electrodes 51b to 58b are formed at the insulating substrate 3b. Further, an inner electrode 12b that constitutes a part of a second coil L2, an inner electrode 13b that constitutes a part of a first capacitor C1, and an inner electrode 14b that constitutes a part of a second capacitor C2 are formed at the insulating substrate 3b. The side electrode 21b is electrically connected to the inner electrode 13b, and the side electrode 24b is electrically connected to the inner electrode 14b. Further, a connection point 34b of the side electrode 22b is electrically connected to a connection point 34a of the inner electrode 13a through a via conductor 34. A connection point 33b of the side electrode 23b is electrically connected to a connection point 33a of the inner electrode 14a through a via conductor 33.

Side electrodes 21c to 24c and dummy electrodes 51c to 58c are formed at the insulating substrate 3c. Further, an inner electrode 12c that constitutes a part of a second coil L2, an inner electrode 13c that constitutes a part of a first capacitor C1, and an inner electrode 14c that constitutes a part of a second capacitor C2 are formed at the insulating substrate 3c. The side electrode 22c is electrically connected to the inner electrode 13c, and the side electrode 23c is electrically connected to the inner electrode 14c.

Side electrodes 21d to 24d and dummy electrodes 51d to 58d are formed at the insulating substrate 3d. Further, an inner electrode 12d that constitutes a part of a second coil L2, an inner electrode 13d that constitutes a part of a first capacitor C1, and an inner electrode 14d that constitutes a part of a second capacitor C2 are formed at the insulating substrate 3d. The side electrode 21d is electrically connected to the inner electrode 13d, and the side electrode 24d is electrically connected to the inner electrode 14d. Further, the inner electrode 12d is electrically connected to the inner electrode 14d. Although not shown, the inner electrodes 12a to 12d are electrically connected to each other through via conductors, and constitute the second coils L2.

Side electrodes 21e to 24e and dummy electrodes 51e to 58e are formed at the insulating substrate 3e. Further, an inner electrode 13e that constitutes a part of a first capacitor C1 and an inner electrode 14e that constitutes a part of a second capacitor C2 are formed at the insulating substrate 3e. The side electrode 22e is electrically connected to the inner electrode 13e, and the side electrode 23e is electrically connected to the inner electrode 14e.

Side electrodes 21f to 24f and dummy electrodes 51f to 58f are formed at the insulating substrate 3f. Further, an inner electrode 11f that constitutes a part of a first coil L1, an inner electrode 13f that constitutes a part of a first capacitor C1, and an inner electrode 14f that constitutes a part of a second capacitor C2 are formed at the insulating substrate 3f. The side electrode 21f is electrically connected to the inner electrode 13f, and the side electrode 24f is electrically connected to the inner electrode 14f. Further, the inner electrode 11f is electrically connected to the inner electrode 14f.

Side electrodes 21g to 24g and dummy electrodes 51g to 58g are formed at the insulating substrate 3g. Further, an inner electrode 11g that constitutes a part of a first coil L1, an inner electrode 13g that constitutes a part of a first capacitor C1, and an inner electrode 14g that constitutes a part of a second capacitor C2 are formed at the insulating substrate 3g. The side electrode 22g is electrically connected to the inner electrode 13g, and the side electrode 23g is electrically connected to the inner electrode 14g.

Side electrodes 21h to 24h and dummy electrodes 51h to 58h are formed at the insulating substrate 3h. Further, an inner electrode 11h that constitutes a part of a first coil L1, an inner electrode 13h that constitutes a part of a first capacitor C1, and an inner electrode 14h that constitutes a part of a second capacitor C2 are formed at the insulating substrate 3h. The side electrode 21h is electrically connected to the inner electrode 13h, and the side electrode 24h is electrically connected to the inner electrode 14h.

Side electrodes 21i to 24i and dummy electrodes 51i to 58i are formed at the insulating substrate 3i. Further, an inner electrode 11i that constitutes a part of a first coil L1, an inner electrode 13i that constitutes a part of a first capacitor C1, and an inner electrode 14i that constitutes a part of a second capacitor C2 are formed at the insulating substrate 3i. The side electrode 22i is electrically connected to the inner electrode 13i, and the side electrode 23i is electrically connected to the inner electrode 14i.

Side electrodes 21j to 24j and dummy electrodes 51j to 58j are formed at the insulating substrate 3j. Further, an inner electrode 11j that constitutes a part of a first coil L1, an inner electrode 13j that constitutes a part of a first capacitor C1, and an inner electrode 14j that constitutes a part of a second capacitor C2 are formed at the insulating substrate 3j. The side electrode 21j is electrically connected to the inner electrode 13j, and the side electrode 24j is electrically connected to the inner electrode 14j. Further, the inner electrode 11j is electrically connected to the inner electrode 13j. Although not shown, the inner electrodes 11f to 11j are electrically connected to each other through via conductors, and constitute the first coils L1.

Side electrodes 21k to 24k and dummy electrodes 51k to 58k are formed at the insulating substrate 3k. Further, an inner electrode 13k that constitutes a part of a first capacitor C1 and an inner electrode 14k that constitutes a part of a second capacitor C2 are formed at the insulating substrate 3k. A connection point 36k of the inner electrode 13k is electrically connected to a connection point 36j of the side electrode 22j through a via conductor 36. A connection point 35k of the inner electrode 14k is electrically connected to a connection point 35j of the side electrode 23j through a via conductor 35.

As shown in FIG. 4, the side electrodes 21b to 21j, the side electrodes 22b to 22j, the side electrodes 23b to 23j, and the side electrodes 24b to 24j are all electrically connected to each other through a corresponding one of the via conductors. It should be noted that side electrodes 21l to 24l are formed at the insulating substrates 3l in correspondence with a corresponding one of the outer electrodes 41 to 44 that are formed at the bottom surface of the insulator 3.

Here, the dummy electrodes 51a to 51k are collectively referred to as dummy electrodes 51, the dummy electrodes 52a to 52k are collectively referred to as dummy electrodes 52, the dummy electrodes 53a to 53k are collectively referred to as dummy electrodes 53, and the dummy electrodes 54a to 54k are collectively referred to as dummy electrodes 54. Further, the dummy electrodes 55a to 55k are collectively referred to as dummy electrodes 55, the dummy electrodes 56a to 56k are collectively referred to as dummy electrodes 56, the dummy electrodes 57a to 57k are collectively referred to as dummy electrodes 57, and the dummy electrodes 58a to 58k are collectively referred to as dummy electrodes 58.

In the electronic component 1, with regard to the plurality of insulating substrates 3a to 3l shown in FIG. 5, at least one of each is placed upon each other, and a plurality of insulating substrates that do not have electrode patterns printed (dummy layers) are placed on sides of two surfaces, that is, an upper surface and a lower surface, of each of the insulating substrates 3a to 3l. By pressure-bonding the plurality of insulating substrates and also the dummy layers, an unfired insulator 3 (glass body) is formed. The formed insulator 3 is fired, and each of the outer electrodes 41 to 44 is formed by plating at a corresponding one of outer portions of the fired insulator 3.

As described above, the electronic component 1 according to the embodiment includes an insulator 3 where a plurality of insulating substrates, each being provided with side electrodes 21 to 24 and inner electrodes 11 to 14, are placed upon each other, and outer electrodes 41 to 44 that are electrically connected to the side electrodes 21 to 24 and that are provided at side surfaces of the insulator 3. The plurality of insulating substrates 3a to 3k are each further provided with dummy electrodes 51 to 58 that are disposed at a corresponding one of two sides of a corresponding one of the side electrodes 21 to 24 with an insulating portion being interposed therebetween as seen from the placement direction. The outer electrodes 41 to 44 are provided from where the side electrodes 21 to 24 are disposed to where the dummy electrodes 51 to 58 are disposed, and are connected to the dummy electrodes 51 to 58 at the side surfaces of the insulator 3.

Therefore, since the plurality of insulating substrates are each further provided with the dummy electrodes 51 to 58 that are disposed at the corresponding one of the two sides of the corresponding one of the side electrodes 21 to 24 with the insulating portion being interposed therebetween when viewed from the placement direction, the electronic component 1 according to the embodiment can suppress occurrence of problems such as electrochemical migration.

### Modifications

(1) In the electronic component 1 described thus far, as shown in FIG. 5, the inner electrodes 13a and 14a that are closest to the top surface of the insulator 3 and the inner electrodes 13k and 14k that are closest to the bottom surface of the insulator 3 are not electrically connected to the side electrodes. However, the disclosure is not limited thereto and thus the inner electrodes 13a and 14a and the inner electrodes 13k and 14k may be electrically connected to the side electrodes.

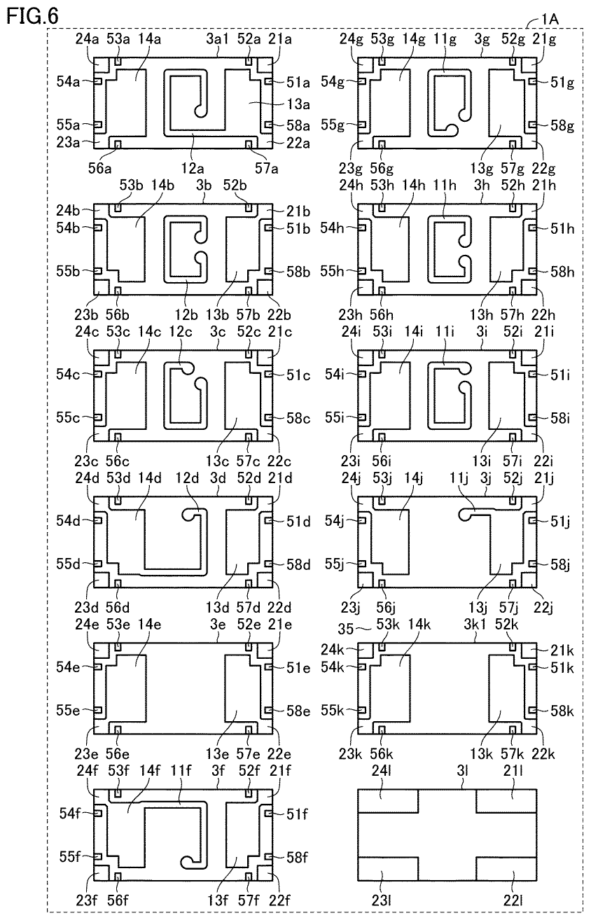

FIG. 6 is an exploded plan view showing a structure of an electronic component 1A according to Modification 1. In the structure of the electronic component 1A according to Modification 1, structural portions that are the same as those of the electronic component 1 according to the embodiment are given the same reference numerals, and detailed descriptions thereof are not repeated.

As shown in FIG. 6, side electrodes 21a to 24a and dummy electrodes 51a to 58a are formed at an insulating substrate 3a. Further, an inner electrode 12a that constitutes a part of a second coil L2, an inner electrode 13a that constitutes a part of a first capacitor C1, and an inner electrode 14a that constitutes a part of a second capacitor C2 are formed at the insulating substrate 3a. The inner electrode 13a is electrically connected to the side electrode 22a, and the inner electrode 14a is electrically connected to the side electrode 23a. Therefore, even if a via conductor 33 is not provided, since the side electrode 23a and a side electrode 23b are electrically connected to each other through the outer electrode 43 (see FIG. 1), the inner electrode 14a is electrically connected to the side electrode 23b. Even if a via conductor 34 is not provided, since the side electrode 22a and a side electrode 22b are electrically connected to each other through the outer electrode 42 (see FIG. 1), the inner electrode 13a is electrically connected to the side electrode 22b.

Side electrodes 21k to 24k and dummy electrodes 51k to 58k are formed at an insulating substrate 3k1. Further, an inner electrode 13k that constitutes a part of a first capacitor C1, and an inner electrode 14k that constitutes a part of a second capacitor C2 are formed at the insulating substrate 3k1. The inner electrode 13k is electrically connected to the side electrode 22k, and the inner electrode 14k is electrically connected to the side electrode 23k. Therefore, even if a via conductor 35 is not provided, since a side electrode 23j and the side electrode 23k are electrically connected to each other through the outer electrode 43 (see FIG. 1), the inner electrode 14k is electrically connected to the side electrode 23j. Even if a via conductor 36 is not provided, since the side electrode 22j and the side electrode 22k are electrically connected to each other through the outer electrode 42 (see FIG. 1), the inner electrode 13k is electrically connected to the side electrode 22j.

The electronic component 1A according to Modification 1 can ensure design freedom by using the structure shown in FIG. 6.

(2) In the electronic component 1 described thus far, as shown in FIG. 5, the dummy electrodes 51 to 58 are formed in all of the layers of the side electrodes 21 to 24. However, the disclosure is not limited thereto, and thus, in the electronic component, the dummy electrodes 51 to 58 may be formed in required layers among the layers of the side electrodes 21 to 24.

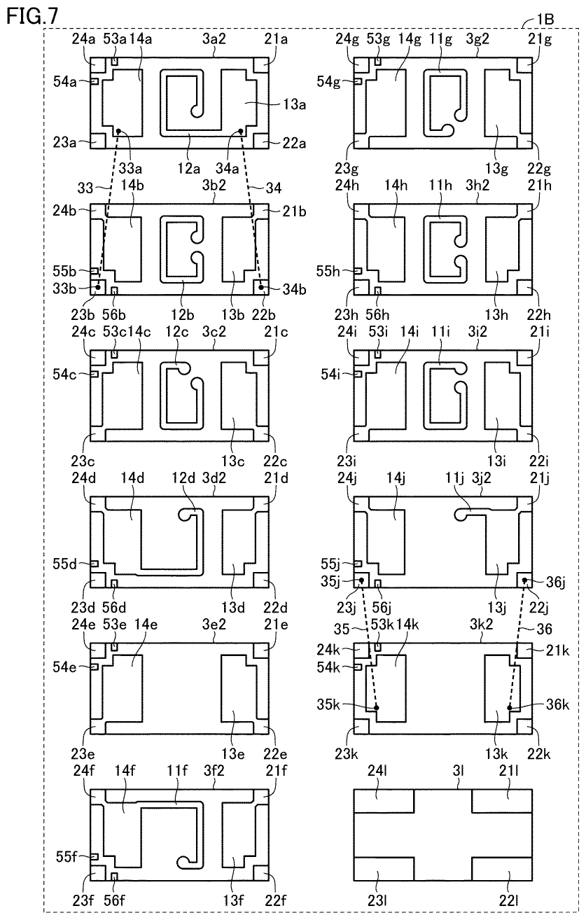

FIG. 7 is an exploded plan view showing a structure of an electronic component 1B according to Modification 2. It should be noted that, in the structure of the electronic component 1B according to Modification 2, structural portions that are the same as those of the electronic component 1 according to the embodiment are given the same reference numerals, and detailed descriptions thereof are not repeated.

Dummy electrodes 55 and 56 are formed only near a side electrode 23 at each of an insulating substrate 3b2, an insulating substrate 3d2, an insulating substrate 3f2, an insulating substrate 3h2, and an insulating substrate 3j2. Further, dummy electrodes 53 and 54 are formed only near a side electrode 24 at each of an insulating substrate 3a2, an insulating substrate 3c2, an insulating substrate 3e2, an insulating substrate 3g2, an insulating substrate 3i2, and an insulating substrate 3k2.

In the electronic component 1B according to Modification 2, since, by using the structure shown in FIG. 7, the dummy electrodes are provided only at an electrode (such as the side electrode 23 or the side electrode 24) where electrochemical migration caused by a voltage difference may occur, it is not necessary to provide unnecessary dummy electrodes and thus a wider region where inner electrodes can be formed at the insulating substrates can be ensured.

(3) In the electronic component 1 described thus far, as shown in FIG. 3, the number of dummy electrodes 51 and the number of dummy electrodes 52 formed on a corresponding one of two sides of the side electrode 21 are one. However, the disclosure is not limited thereto, and, in the electronic component, a plurality of dummy electrodes may be formed on each of the two sides of the side electrode 21.

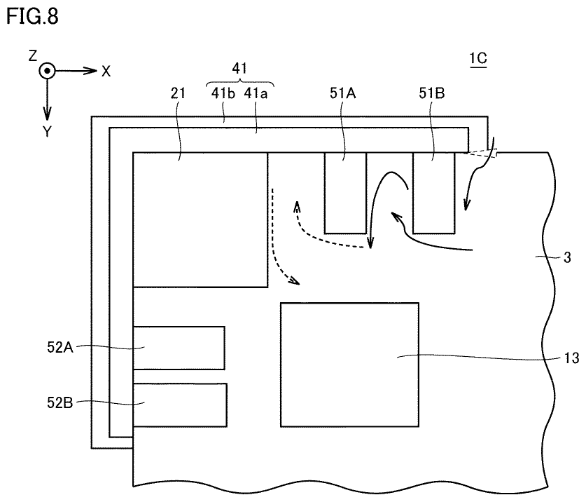

FIG. 8 is a plan view of the vicinity of one outer electrode of an electronic component according to Modification 3. It should be noted that, in a structure of an electronic component 1C according to Modification 3, structural portions that are the same as those of the electronic component 1 according to the embodiment are given the same reference numerals, and detailed descriptions thereof are not repeated.

In the electronic component 1C according to Modification 3, dummy electrodes 51A and 52A (first dummy electrodes) are provided so as to be disposed on a corresponding one of two sides of a side electrode 21 with an insulating portion being interposed therebetween when viewed from the placement direction (the Z direction). Further, the electronic component 1C includes dummy electrodes 51B and 52B (second dummy electrodes) that are provided at positions farther from the side electrode 21 than the dummy electrodes 51A and 52A. An outer electrode 41 is provided from where the side electrode 21 is disposed to where the dummy electrodes 51B and 52B are disposed, and is connected to the dummy electrodes 51A, 51B, 52A, and 52B at side surfaces of the insulator 3. By providing the dummy electrode 51B in addition to the dummy electrode 51A, moisture that entered through a gap cannot reach the side electrode 21 unless the moisture bypasses not only the dummy electrode 51A but also the dummy electrode 51B, and thus it is possible to suppress occurrence of problems such as electrochemical migration occurring between the side electrode 21 and an inner electrode 13. That is, by providing the dummy electrodes 51B and 52B in addition to the dummy electrodes 51A and 52A, it is possible to extend a path extending from an edge of the outer electrode 41 to the side electrode 21 and to make longer an entry path of the moisture that enters the insulator 3.

Although not shown, in the electronic component 1C, a plurality of dummy electrodes may be provided at positions that are farther from the side electrode 21 than the dummy electrodes 51B and 52B. Although the structure of the vicinity of the outer electrode 41 has been described with reference to FIG. 8, in the electronic component 1C, the vicinity of the other outer electrodes 42 to 44 have the same structure. That is, since the dummy electrodes 51 to 54 of the electronic component 1C include dummy electrodes that are close to a corresponding one of the side electrodes 21 to 24 when seen from the placement direction (first dummy electrodes) and dummy electrodes that are far from the corresponding one of the side electrodes 21 to 24 (second dummy electrodes), it is possible to suppress occurrence of problems such as electrochemical migration occurring between the side electrodes and the inner electrodes.

### Forms

(1) An electronic component according to the present disclosure comprises an insulator where a plurality of insulating substrates, each being provided with a side electrode and an inner electrode, are placed upon each other; and outer electrodes that are electrically connected to the side electrodes and that are provided at side surfaces of the insulator. The plurality of insulating substrates are each further provided with dummy electrodes that are disposed on a corresponding one of two sides of the side electrode with an insulating portion being interposed therebetween when viewed from a placement direction, and the outer electrodes are electrically connected to the dummy electrodes at the side surfaces of the insulator.

(2) The electronic component according to (1), wherein the insulator has a first main surface and a second main surface that face each other in the placement direction. Also, a first side electrode that is closest to the first main surface and a second side electrode that is adjacent to the first side electrode at a position closer to the second main surface than the first side electrode are not electrically connected to each other by a via conductor, and a third side electrode that is closest to the second main surface and a fourth side electrode that is adjacent to the third side electrode at a position closer to the first main surface than the third side electrode are not electrically connected to each other by a via conductor.

(3) The electronic component according to (2), wherein, except for the first side electrode and the second side electrode and for the third side electrode and the fourth side electrode, the side electrodes of layers corresponding thereto are electrically connected to each other by a corresponding one of the via conductors.

(4) The electronic component according to (3), wherein the via conductors are directly electrically connected to the outer electrodes.

(5) The electronic component according to any one of (1) to (4), wherein distances between the dummy electrodes and the inner electrodes corresponding thereto are larger than distances between the side electrodes and the inner electrodes corresponding thereto.

(6) The electronic component according to any one of (1) to (5), wherein shapes of the dummy electrodes when viewed from the placement direction are each a rectangular shape whose side that does not contact the outer electrode corresponding thereto is longer than a side thereof that contacts the outer electrode corresponding thereto.

(7) The electronic component according to any one of (1) to (6), wherein the dummy electrodes include a first dummy electrode that is close to a corresponding one of the side electrodes when viewed from the placement direction and a second dummy electrode that is far from the corresponding one of the side electrodes when viewed from the placement direction.

(8) The electronic component according to any one of (1) to (7), wherein the outer electrodes each include a first outer electrode layer that is provided at a corresponding one of the side surfaces of the insulator and a second outer electrode layer that covers the first outer electrode layer, and each of the first outer electrode layers contacts the side electrode corresponding thereto and the dummy electrode corresponding thereto.

(9) The electronic component according to (8), wherein each of the first outer electrode layers is made of nickel, and each of the second outer electrode layers is made of gold.

(10) The electronic component according to any one of (1) to (9), wherein each of the side electrodes is provided at a corresponding one of four corners of the insulator when viewed from the placement direction, and has a shape that is a square shape when viewed from the placement direction.

(11) The electronic component according to any one of (1) to (10), wherein the inner electrodes include at least an electrode that constitutes a part of a coil and an electrode that constitutes a part of a capacitor, and constitute a filter circuit in the insulator.

It is to be understood that the embodiment described here is illustrative on all points and is not restrictive. The scope of the present disclosure is defined by the claims rather than by the description above, and is intended to include all changes that fall within the scope of the claims and equivalence thereof.

What is claimed is:

1. An electronic component comprising:
an insulator including a plurality of insulating substrates, each having a side electrode and an inner electrode, that are placed upon each other; and
outer electrodes that are electrically connected to the side electrodes and that are at side surfaces of the insulator,
wherein
the plurality of insulating substrates each further includes dummy electrodes that are on a corresponding one of two sides of the side electrode with an insulating portion being interposed therebetween when viewed from a placement direction, and
the outer electrodes are electrically connected to the dummy electrodes at the side surfaces of the insulator.

2. The electronic component according to claim 1, wherein
the insulator has a first main surface and a second main surface that face each other in the placement direction, and
a first side electrode that is closest to the first main surface and a second side electrode that is adjacent to the first side electrode at a position closer to the second main surface than the first side electrode are not electrically connected to each other by a via conductor, and a third side electrode that is closest to the second main surface and a fourth side electrode that is adjacent to the third side electrode at a position closer to the first main surface than the third side electrode are not electrically connected to each other by a via conductor.

3. The electronic component according to claim 2, wherein
except for the first side electrode and the second side electrode and for the third side electrode and the fourth side electrode, the side electrodes of layers corresponding thereto are electrically connected to each other by a corresponding one of the via conductors.

4. The electronic component according to claim 3, wherein the via conductors are directly electrically connected to the outer electrodes.

5. The electronic component according to claim 1, wherein
distances between the dummy electrodes and the inner electrodes corresponding thereto are larger than distances between the side electrodes and the inner electrodes corresponding thereto.

6. The electronic component according to claim 1, wherein
shapes of the dummy electrodes when viewed from the placement direction are each a rectangular shape whose side that does not contact the outer electrode corresponding thereto is longer than a side thereof that contacts the outer electrode corresponding thereto.

7. The electronic component according to claim 1, wherein
the dummy electrodes include a first dummy electrode that is close to a corresponding one of the side electrodes when viewed from the placement direction and a second dummy electrode that is far from the corresponding one of the side electrodes when viewed from the placement direction.

8. The electronic component according to claim 1, wherein
the outer electrodes each include a first outer electrode layer that is at a corresponding one of the side surfaces of the insulator and a second outer electrode layer that covers the first outer electrode layer, and each of the first outer electrode layers contacts the side electrode corresponding thereto and the dummy electrode corresponding thereto.

9. The electronic component according to claim 8, wherein
each of the first outer electrode layers includes nickel, and each of the second outer electrode layers includes gold.

10. The electronic component according to claim 1, wherein
each of the side electrodes is at a corresponding one of four corners of the insulator when viewed from the placement direction, and has a shape that is a square shape when viewed from the placement direction.

11. The electronic component according to claim 1, wherein
the inner electrodes include at least an electrode that configures a part of a coil and an electrode that configures a part of a capacitor, and configure a filter circuit in the insulator.

12. The electronic component according to claim 2, wherein
distances between the dummy electrodes and the inner electrodes corresponding thereto are larger than distances between the side electrodes and the inner electrodes corresponding thereto.

13. The electronic component according to claim 3, wherein
distances between the dummy electrodes and the inner electrodes corresponding thereto are larger than distances between the side electrodes and the inner electrodes corresponding thereto.

14. The electronic component according to claim 2, wherein
shapes of the dummy electrodes when viewed from the placement direction are each a rectangular shape whose side that does not contact the outer electrode corresponding thereto is longer than a side thereof that contacts the outer electrode corresponding thereto.

15. The electronic component according to claim 3, wherein
shapes of the dummy electrodes when viewed from the placement direction are each a rectangular shape whose side that does not contact the outer electrode corresponding thereto is longer than a side thereof that contacts the outer electrode corresponding thereto.

16. The electronic component according to claim 2, wherein
the dummy electrodes include a first dummy electrode that is close to a corresponding one of the side electrodes when viewed from the placement direction and a second dummy electrode that is far from the corresponding one of the side electrodes when viewed from the placement direction.

17. The electronic component according to claim 3, wherein
the dummy electrodes include a first dummy electrode that is close to a corresponding one of the side electrodes when viewed from the placement direction and a second dummy electrode that is far from the corresponding one of the side electrodes when viewed from the placement direction.

18. The electronic component according to claim 2, wherein
the outer electrodes each include a first outer electrode layer that is at a corresponding one of the side surfaces of the insulator and a second outer electrode layer that covers the first outer electrode layer, and each of the first outer electrode layers contacts the side electrode corresponding thereto and the dummy electrode corresponding thereto.

19. The electronic component according to claim 2, wherein
each of the side electrodes is at a corresponding one of four corners of the insulator when viewed from the placement direction, and has a shape that is a square shape when viewed from the placement direction.

20. The electronic component according to claim 2, wherein
the inner electrodes include at least an electrode that configures a part of a coil and an electrode that configures a part of a capacitor, and configure a filter circuit in the insulator.
